(19) United States
(12) Patent Application Publication
(10) Pub. No.: US 2014/0182516 A1
(43) Pub. Date: Jul. 3, 2014

(54) APPARATUS FOR FABRICATING INGOT

(71) Applicant: L G INNOTEK CO., LTD., Seoul (KR)

(72) Inventors: Chang Hyun Son, Jung-gu (KR); Bum Sup Kim, Jung-gu (KR)

(73) Assignee: LG INNOTEK CO., LTD., Seoul (KR)

(21) Appl. No.: 14/124,976

(22) PCT Filed: Jun. 7, 2012
(86) PCT No.: PCT/KR2012/004499

§ 371 Date: Mar. 3, 2014

(30) Foreign Application Priority Data
Jun. 7, 2011 (KR) 10-2011-0054622

(51) Int. Cl. C30B 23/00

(52) U.S. Cl. CPC C30B 23/002
USPC 118/726

(57) ABSTRACT

The present invention relates to an apparatus for fabricating ingot including a crucible to accommodate a material, a top cover enclosing the circumference of the temperature difference compensative part, and a heat insulator to be disposed on the top cover.

### TECHNICAL FIELD

The disclosure relates to an apparatus for fabricating ingot.

### BACKGROUND ART

Generally, the importance of material is definitive, and in practice, the material is a key factor in determining property and performance index of final product in the various fields of industry such as electricity, electronics and machine parts.

SiC has excellent thermal stability and superior oxidation resistance. Additionally, SiC has a good thermal conductivity of approximately 4.6W/Cm° C., and it is advantageous to be produced as a large substrate with a diameter of 2 inches or more. Especially, SiC single crystal growth technology has been secured reliably, so industrial production technology for a substrate has been most advanced.

For SiC, a method for growing SiC single crystal by sublimation-recrystallization way using a seed crystal has been suggested. SiC powder as material is received into a crucible and SiC single crystal as the seed crystal is located at the top thereof. By forming temperature gradient between the material and the seed crystal, the material within the crucible is diffused to the seed crystal side and re-crystallized, and single crystal is grown.

However, while the SiC is growing, a temperature difference between the center and periphery of the seed crystal holder for fixing the seed crystal is produced. As a result, the single crystal growing from the seed crystal is also affected by the temperature difference, so the center of the single crystal bulges. In addition, due to such a temperature difference, defects may be produced at the periphery of the single crystal.

### DISCLOSURE OF INVENTION

### Technical Problem

The embodiment provides a method of growing a high quality single crystal.

### Solution to Problem

The apparatus for fabricating ingot according to an embodiment of the present invention includes: a crucible for accommodating a material; a temperature difference compensative part arranged on the material; a top cover enclosing the circumference of the temperature difference compensative part; and a heat insulator arranged on the top cover.

### Advantageous Effects of Invention

The apparatus for fabricating ingot according to the embodiment includes a temperature difference compensative part and a heat insulator. The temperature difference compensative part contacts a seed crystal holder for fixing a seed crystal.

The temperature at the center of the seed crystal is raised by forming thicker the temperature difference compensative part corresponding to the center of the seed crystal. That is, the temperature difference compensative part can keep the center of the seed crystal to be raised-temperature.

Through this configuration, the temperature difference between the center and the periphery of the seed crystal may be reduced. That is, the temperature of the seed crystal may be maintained uniformly. Accordingly, defect in the periphery of the seed crystal can be minimized. Additionally, the bulging of the center of single crystal grown from the seed crystal, which is caused by the temperature difference between the center and the periphery of the seed crystal, may be prevented, and thus the single crystal may be utilized more efficiently.

Further, the heat insulator may be incorporated into various shapes and structures, so the temperature of the seed crystal may be maintained uniformly more easily.

### BRIEF DESCRIPTION OF DRAWINGS

FIG. 1 is a cross-sectional view showing an apparatus for fabricating ingot according to a first embodiment.

FIG. 2 is an exploded-perspective view showing a heat insulator, a temperature difference compensative part and a top cover of an apparatus for fabricating ingot according to a first embodiment.

FIG. 3 is a cross-sectional view showing an apparatus for fabricating ingot according to a second embodiment.

FIG. 4 is an exploded-perspective view showing a heat insulator, a temperature difference compensative part and a top cover of an apparatus for fabricating ingot according to a second embodiment.

FIG. 5 is a cross-sectional view showing an apparatus for fabricating ingot according to a third embodiment.

FIG. 6 is an exploded-perspective view showing a heat insulator, a temperature difference compensative part and a top cover of an apparatus for fabricating ingot according to a third embodiment.

### MODE FOR THE INVENTION

In the description of the embodiments, it will be understood that, the description that respective layer (film), a region, a pattern or a structure is formed “on” or “under” thereof includes all that they are formed directly “on” or “under” another layer (film), another region, another pattern or another structure and another layer is interposed therebetween. Such a position of “on” or “under” is described with reference to the drawings.

It is also understood that the thickness and size of each layer(film), region, pattern or structure in the drawings may be modified for clarity and convenience for description and thus actual size is not reflected.

Hereinafter, exemplary embodiments will be described in detail with reference to the accompanying drawings.

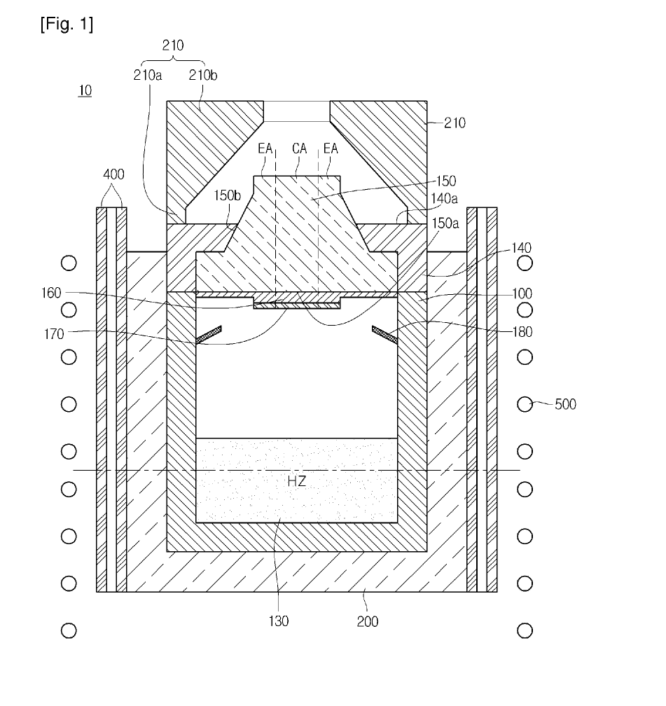

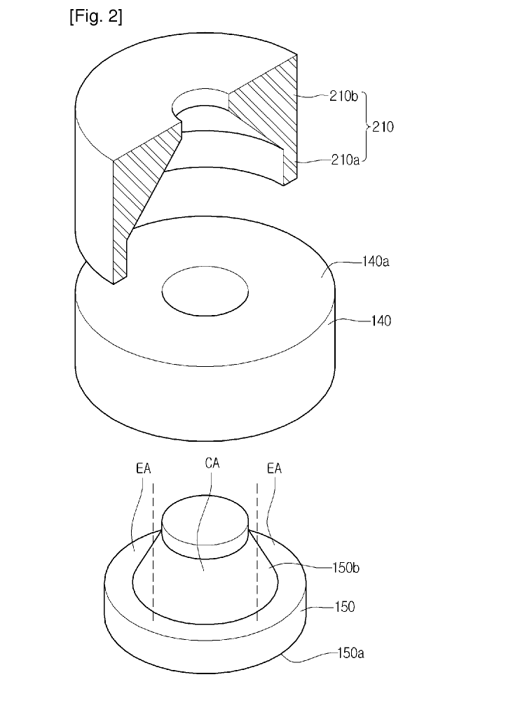

Referring to FIGS. 1 to 2, an apparatus for fabricating ingot according to a first embodiment will be described in detail. FIG. 1 is a cross-sectional view showing an apparatus for fabricating ingot according to a first embodiment. FIG. 2 is an exploded-perspective view showing a heat insulator, a temperature difference compensative part and a top cover of an apparatus for fabricating ingot according to the first embodiment.

Referring to FIGS. 1 to 2, the apparatus for fabricating ingot 10 according to the first embodiment includes a crucible 100, a top cover 140, a temperature difference compensative part 150, a seed crystal holder 160, a focusing tube 180, a first heat insulator 200, a second heat insulator 210, a quartz pipe 400, and a heat generation inductive part 500.

The crucible 100 may accommodate a material 130. The material 130 may include silicon and carbon. More specifically, the material 130 may include SiC compound. The crucible 100 may accommodate SiC powder or polycarbosilane.

The crucible 100 may be shaped as a cylinder to accommodate the material 130.

The crucible 100 may contain substances having melting point higher than the sub-limation temperature of SiC.

As an example, the crucible 100 may be fabricated with graphite.

In addition, the crucible 100 may be fabricated by applying a substance having melting point higher than the sublimation temperature of SiC on the graphite. Here, as the substance to be applied on the graphite, it is desirable to use a chemically inactive substance to silicon and hydrogen at the temperature of the SiC single crystal being grown. For example, metal carbides or metal nitrides may be used. Especially, carbides containing carbon and a mixture containing at least two of Ta, Hf, Nb, Zr, W and V may be applied on the graphite. In addition, nitrides containing nitrogen and a mixture containing at least two of Ta, Hf, Nb, Zr, W and V may be applied on the graphite.

A top cover 140 may be provided at the upper part of the crucible 100. The top cover 140 may seal up the crucible 100. That is, the top cover 140 may seal up the crucible so that a reaction occurs therein.

The top cover 140 may contain graphite.

The top cover 140 may enclose a part of the temperature difference compensative part 150. That is, the top cover 140 may be located in the upper circumference of the crucible 100. The top cover 140 may minimize the leakage of material gas while the single crystal is growing. Accordingly, the top cover 140 may cover a part of the temperature difference compensative part 150. More specifically, the top cover 140 may cover an upper part of the temperature difference compensative part 150, and thus may seal up the crucible 100.

Next, the temperature difference compensative part 150 is located on the material 130. The seed crystal holder 160 is placed at the lower face 150a of the temperature difference compensative part 150. The temperature difference compensative part 150 may contact directly the seed crystal holder 160. Thus, according to the structural change of the temperature difference compensative part 150, the temperature gradient of the seed crystal holder 160 can be controlled easily. As a result, uniform temperature gradient of the seed crystal holder 160 may be established.

The temperature difference compensative part 150 may contain graphite. The temperature difference compensative part 150 may contain substance having higher density than the crucible. That is, the temperature difference compensative part 150 may contain graphite of high density. Specifically, the temperature difference compensative part 150 may contain graphite having density of 1.84 g/cm³ or more. As a result, the temperature at the center of the seed crystal holder 160 can be raised effectively.

The temperature difference compensative part 150 includes the center part (CA) corresponding to the center of the seed crystal 170 and the exterior EA to be located at the circumference of the center (CA). Further, the thickness of the center (CA) may be greater than the thickness of the exterior (EA).

In addition, the temperature difference compensative part 150 may include a slope 150b inclined toward the upper face 140a of the top cover 140.

Generally, the temperature of the crucible 100 decreases gradually from an outer wall toward the center. Accordingly, the temperature at the center of the seed crystal 170 is lower than the temperature at the periphery of the seed crystal 170.

According to the embodiment, since the temperature difference compensative part 150 corresponding to the center of the seed crystal 170 is formed thicker, the temperature at the center of the seed crystal 170 may be raised. That is, the center (CA) can maintain the center of the seed crystal 170 at a high temperature.

Through this configuration, the temperature difference between the center of the seed crystal 170 and the periphery of the seed crystal 170 may be reduced. That is, the temperature of the seed crystal 170 may be maintained uniformly. Accordingly, defect in the circumference of the seed crystal 170 can be minimized. Moreover, the bulging of the center of the single crystal grown from the seed crystal 170 by the temperature difference between the center and the periphery of the seed crystal may be prevented. As a result, the single crystal may be utilized more efficiently.

The seed crystal holder 160 is located at the bottom of the temperature difference compensative part 150. That is, the seed crystal holder 160 is disposed on the material 130.

The seed crystal holder 160 may fix the seed crystal 170. The seed crystal holder 160 may contain graphite of high density.

Next, the focusing tube 180 is located within the crucible 100. The focusing tube 180 may be located at a position where single crystal is growing. The focusing tube 180 may narrow a pathway of sublimed SiC gas to focus the diffusion of sublimed SiC into the seed crystal 170. Through this process, a growth rate of crystal may be raised.

Then, the first heat insulator 200 encloses the crucible 100. The first heat insulator 200 keeps the crucible 100 at crystal growth temperature. The first heat insulator 200 may use a graphite felt since the crystal growth temperature of SiC is very high. Specifically, the first heat insulator 200 may use the graphite felt fabricated as a cylinder form of a predetermined thickness by compressing graphite fiber. Additionally, the first heat insulator 200 may be formed as a multilayer to enclose the crucible 100.

The secondary heat insulator 210 is arranged on the top cover 140. The secondary heat insulator 210 may be disposed around the exterior EA of the temperature difference compensative part 150.

The secondary heat insulator 210 can lower the temperature of the crucible 100. Through this configuration, the temperature difference between the center and the periphery of the seed crystal may be lowered.

The secondary heat insulator 210 includes an extended part 210a extended to a length direction of the crucible 100 at the top cover 140 and a crossed part 210b formed in the direction crossed to the extended part 210a. The extended part 210a and the crossed part 210b may have various shapes.

The secondary heat insulator 210 may contain graphite.

Then, the quartz pipe 400 is located at the outer circumference of the crucible 100. The quartz pipe 400 is inserted into the outer circumference of the crucible 100. The quartz pipe 400 can block the heat being transmitted from the heat generation inductive part 500 to the inside of single crystal growth unit. The quartz pipe 400 may be a hollow pipe. Cooling water may circulate the internal space of the quartz pipe 400. Thus, the quartz pipe 400 can control a growth rate, growth size, etc. of the single crystal more exactly.

The heat generation inductive part 500 is located in the outside of the crucible 100. As an example, the heat generation inductive part 500 may be a high frequency inductive coil. By flowing high frequency current in a high frequency inductive coil, the heat generation inductive part 500 and the crucible 100 may be heated. That is, the material contained in the crucible 100 may be heated to a desired temperature using the heat generation inductive part.

The center of the heat generation inductive part 500 that is inductively heated is formed at the position lower than the center of the crucible 100. Accordingly, a temperature gradient having different heating temperature areas is formed in upper and lower part of the crucible 100. That is, since a hot zone (HZ) of the center of heat generation inductive part 500 is formed at the position relatively lower than the center of the crucible 100, the temperature of the lower part of the crucible 100 is higher than the temperature of the upper part of the crucible 100 on the basis of the hot zone (HZ). In addition, the temperature of internal center of the crucible 100 along the exterior direction is high. Due to such a temperature gradient, sublimation of SiC material occurs and sublimed SiC gas moves to the surface of the seed crystal 170 having relatively lower temperature. Thus, the SiC gas is re-crystallized and grown into a single crystal.

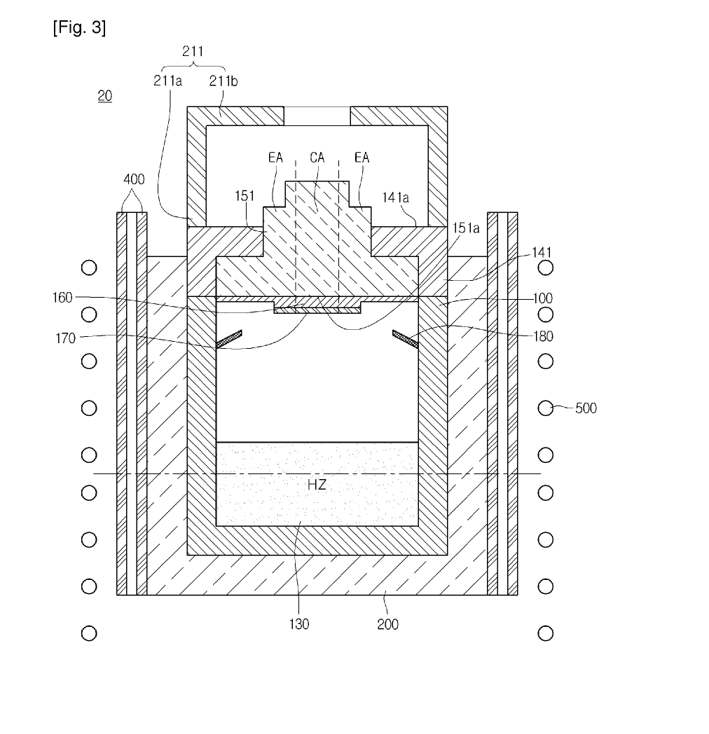

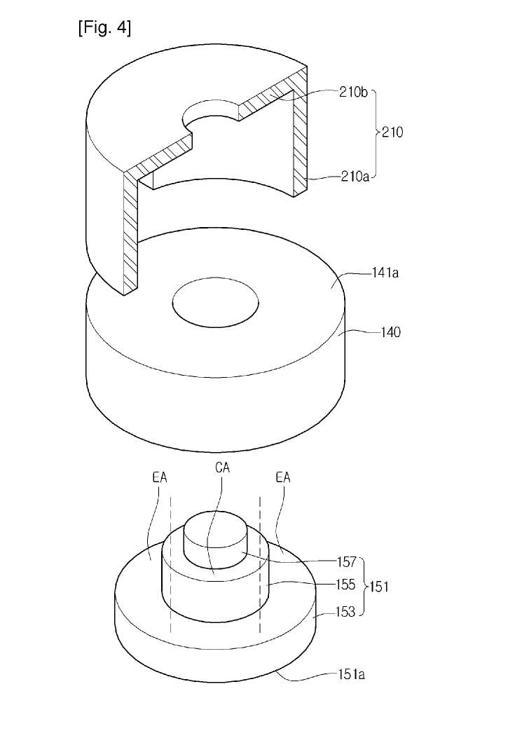

Hereinafter, referring to FIGS. 3 to 4, the apparatus for fabricating ingot will be described in detail according to a secondary embodiment. For clear and simple description, specified descriptions identical or similar to the first embodiment will be omitted.

FIG. 3 is a cross-sectional view showing the apparatus for fabricating ingot according to the secondary embodiment. FIG. 4 is an exploded-perspective view showing a heat insulator, a temperature difference compensative part and a top cover of the apparatus for fabricating ingot according to the secondary embodiment.

Referring FIGS. 3 to 4, the apparatus for fabricating ingot 20 according to the secondary embodiment includes the temperature difference compensative part 151 and the secondary heat insulator 211.

The temperature difference compensative part 151 may include the first temperature difference compensative part 153, the secondary temperature difference compensative part 155 and the third temperature difference compensative part 157.

The first temperature difference compensative part 153 is disposed on the upper face 141a of the top cover 141.

The secondary temperature difference compensative part 155 is disposed on the upper face of the first temperature difference compensative part 153 and is stepped from the first temperature difference compensative part 153.

The third temperature difference compensative part 157 is disposed on the upper face of the secondary temperature difference compensative part 155 and is stepped from the secondary temperature difference compensative part 155.

The temperature difference compensative part 151 may have a shape of stairs.

The secondary heat insulator 211 comprises an extended part 211a and a crossed part 211b, and the extended part 211a and the crossed part 211b may have various shapes and structures.

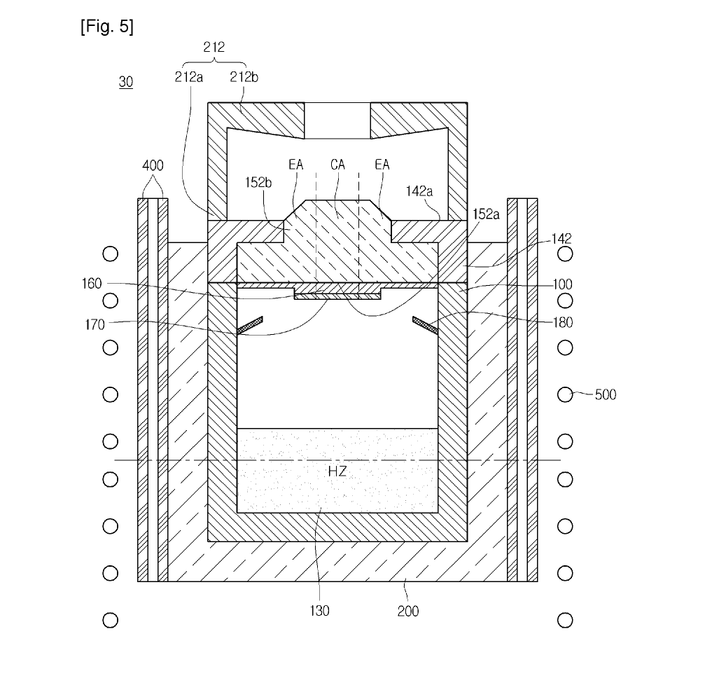

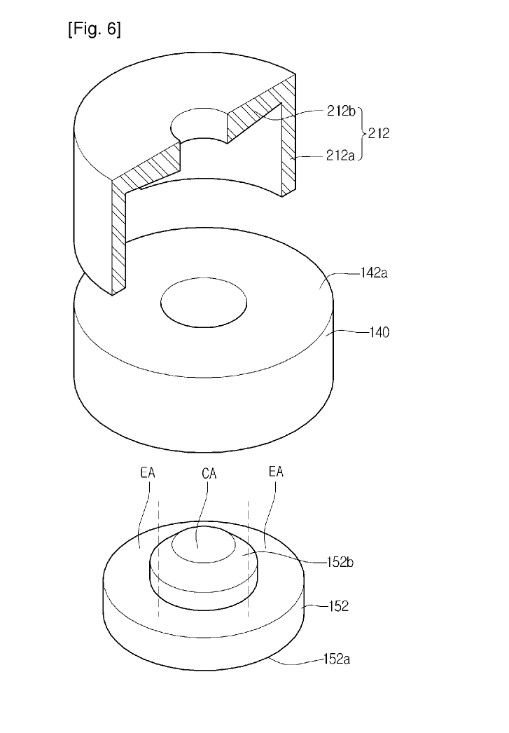

Hereinafter, referring to FIGS. 5 to 6, the apparatus for fabricating ingot according to the third embodiment will be described.

FIG. 5 is a cross-sectional view showing the apparatus for fabricating ingot according to the third embodiment. FIG. 6 is an exploded-perspective view showing the apparatus for fabricating ingot according to the third embodiment.

Referring to FIGS. 5 to 6, the apparatus for fabricating ingot 30 according to the third embodiment includes the temperature difference compensative part 152 and the secondary heat insulator 212.

The temperature difference compensative part 152 may include a slope 152b being inclined to the upper face 142a of the top cover 142. That is, the center (CA) as the center of the temperature difference compensative part 152 may be thick since a slope 152b is inclined downward from the center of the crucible 100.

The secondary heat insulator 212 may have various shapes and structures.

Although example embodiments have been described, those skilled in the art will readily appreciate that many modifications are possible in example embodiments without materially departing from the novel teachings and advantages of example embodiments. Accordingly, all such modifications are intended to be included within the scope of the claims.

Further, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

1. An apparatus for fabricating ingot comprising:
a crucible to accommodate the material;
a temperature difference compensative part to be located on the material;
a top cover enclosing a part of the temperature difference compensative part; and
a heat insulator to be located on the top cover.

2. The apparatus for fabricating ingot of claim 1, wherein a seed crystal holder for fixing the seed crystal is located at the lower part of the temperature difference compensative part, and the temperature difference compensative part contacts the seed crystal holder.

3. The apparatus for fabricating ingot of claim 2, wherein the temperature difference compensative part has a protruded shape with respect to the upper face of the top cover.

4. The apparatus for fabricating ingot of claim 3, wherein the temperature difference compensative part comprises a slope inclined to the upper face of the top cover.

5. The apparatus for fabricating ingot of claim 3, wherein the temperature difference compensative part comprises:
a first difference compensative part that is disposed on the upper face of the top cover;
a secondary temperature difference compensative part that is disposed on the upper face of the first temperature difference compensative part and is stepped from the first temperature difference compensative part; and
a third temperature difference compensative part that is disposed on the upper face of the secondary temperature difference compensative part and is stepped from the secondary temperature difference compensative part.

6. The apparatus for fabricating ingot of claim 5, wherein the temperature difference compensative part has a shape of stairs.

7. The apparatus for fabricating ingot of claim 2, wherein the temperature difference compensative part comprises the center corresponding to the center of the seed crystal holder and the exterior part that is disposed at the outer circumference of the center wherein the thickness of the center is greater than the thickness of the exterior part.

8. The apparatus for fabricating ingot of claim 7, wherein the temperature difference compensative part comprises a substance having higher density than the crucible.

9. The apparatus for fabricating ingot of claim 8, wherein the temperature difference compensative part comprises graphite.

10. The apparatus for fabricating ingot of claim 9, wherein the temperature difference compensative part has a density greater than 1.84 g/cm³.

11. The apparatus for fabricating ingot of claim 1, wherein the heat heat insulator is located around the exterior part.

12. The apparatus for fabricating ingot of claim 11, wherein the heat insulator comprises an extended part that is extended to a length direction of the crucible at the top cover and a crossed part that is formed in the direction crossed to the extended part.

13. The apparatus for fabricating ingot of claim 12, wherein the crossed part is located on the temperature difference compensative part.

14. The apparatus for fabricating ingot of claim 12, wherein the crossed part is located on the exterior part.

15. The apparatus for fabricating ingot of claim 12, wherein the heat heat insulator comprises graphite.

16. The apparatus for fabricating ingot of claim 1, wherein the top cover and the temperature difference compensative part seal up the crucible.
